(19) United States
(12) Patent Application Publication
(10) Pub. No.: US 2026/0029457 A1
(43) Pub. Date: Jan. 29, 2026

(54) DETECTION APPARATUS AND DETECTION METHOD FOR LIGHT-EMITTING ELEMENTS

(71) Applicant: THE HONG KONG UNIVERSITY OF SCIENCE AND TECHNOLOGY (GUANGZHOU), Guangzhou (CN)

(72) Inventors: Yunda Wang, Guangzhou (CN); Qinhua Guo, Guangzhou (CN)

(21) Appl. No.: 19/342,658

(22) Filed: Sep. 28, 2025

Related U.S. Application Data
(63) Continuation-in-part of application No. PCT/CN2024/082143, filed on Mar. 18, 2024.

(30) Foreign Application Priority Data
Mar. 29, 2023 (CN) 202310325281.7

(51) Int. Cl. G01R 31/26; G01R 1/067; G01R 1/24

(52) U.S. Cl. CPC G01R 31/2635; G01R 1/06744; G01R 1/24

(57) ABSTRACT

Provided is a detection apparatus and a detection method for light-emitting elements. The detection apparatus includes a substrate, first signal lines, and second signal lines, where the first signal lines are disposed on the substrate and extend along a first direction; the first signal lines are configured to transmit a first-type signal to to-be-detected elements; the second signal lines are disposed on the substrate and extend along a second direction; the first direction intersects the second direction; the second signal lines are configured to transmit a second-type signal to the to-be-detected elements; at least some adjacent first signal lines and at least some adjacent second signal lines jointly define at least one detection region on the substrate for accommodating the to-be-detected elements; and the same first signal line is configured to be electrically connected to a plurality of to-be-detected elements located in different detection regions.

### CROSS REFERENCE TO RELATED APPLICATIONS

The present application is a Continuation-In-Part application of PCT Application No. PCT/CN2024/082143 filed on Mar. 18, 2024, which claims the benefit of Chinese Patent Application No. 202310325281.7 filed on Mar. 29, 2023. All the above are hereby incorporated by reference in their entirety.

### TECHNICAL FIELD

The present disclosure relates to the technical field of detection devices, and in particular to a detection apparatus and a detection method for light-emitting elements.

### BACKGROUND

With the development of science and technology, the complexity of electronic devices gradually increases, and electrical components in the electronic devices tend to be miniaturized. By reducing the size of electrical components, more electrical components can be integrated within a limited space, thereby improving the user experience.

During the manufacturing process, miniaturized electrical components face the issue of low yield, necessitating testing to identify defective components. However, in some cases, the sheer number of miniaturized electrical components makes the efficient batch detection of these electrical components an urgent problem to be solved.

### SUMMARY

An embodiment of the present disclosure provides a detection apparatus and a detection method for light-emitting elements, which can achieve batch detection.

According to a first aspect, embodiments of the present disclosure provide a detection apparatus, including: a substrate; a plurality of first signal lines, and a plurality of second signal lines, where the first signal lines are disposed on the substrate and extend along a first direction; and the first signal lines are configured to transmit a first-type signal to to-be-detected elements; and the second signal lines are disposed on the substrate and extend along a second direction; the first direction intersects the second direction; the second signal lines are configured to transmit a second-type signal to the to-be-detected elements; at least two adjacent ones of the first signal lines and at least two adjacent ones of the second signal lines jointly define at least one detection region on the substrate for accommodating the to-be-detected elements; and the same first signal line is configured to be electrically connected to a plurality of to-be-detected elements located in different detection regions.

In some embodiments, the same second signal line is configured to be electrically connected to a plurality of to-be-detected elements located in different detection regions.

In some embodiments, the detection apparatus further includes a first conductive portion located in the detection region and connected to the first signal line, where the first signal line is connected to the to-be-detected element through the first conductive portion; and/or the detection apparatus further includes a second conductive portion located in the detection region and connected to the second signal line; and the second signal line is connected to the to-be-detected element through the second conductive portion.

In some embodiments, the detection apparatus further includes a driving circuit disposed in the detection region, where the driving circuit is connected to the to-be-detected element; and the first signal line and the second signal line are connected to the driving circuit to control turn-on or turn-off of the driving circuit, thereby controlling an operating state of the to-be-detected element.

In some embodiments, each of the at least one detection region includes a space for accommodating a plurality of to-be-detected elements;
the plurality of first signal lines include at least one of first signal lines connected in one-to-one correspondence to at least one of the to-be-detected elements located in the same detection region and/or a first signal line connected to at least one of the to-be-detected elements located in the same detection region; and
the plurality of second signal lines include at least one of second signal lines connected in one-to-one correspondence to at least one of the to-be-detected elements located in the same detection region and/or a second signal line connected to at least one of the to-be-detected elements located in the same detection region.

In some embodiments, an arrangement direction of the plurality of to-be-detected elements located in the same detection region is the same as an arrangement direction of the correspondingly connected first signal lines.

In some embodiments, an arrangement order of the plurality of to-be-detected elements located in the same detection region is the same as an arrangement order of the correspondingly connected first signal lines.

In some embodiments, the substrate includes a plurality of island structures spaced apart from each other, and connection portions configured to connect adjacent island structures; and the island structures each are configured to provide a space for accommodating a plurality of to-be-detected elements.

In some embodiments, the connection portions each are provided with a weakened portion; and a structural strength of the weakened portion is less than a structural strength at another position on the connection portion, such that the weakened portion serves as a disconnection position for disconnecting connected island structures.

In some embodiments, the connection portions each include a base and a metal wiring layer stacked on a side of the base; and/or the connection portions each include highly doped polycrystalline silicon;
the plurality of first signal lines are respectively disposed on the connection portions; and/or
the plurality of second signal lines are respectively disposed on the connection portions.

In some embodiments, the island structures are made of a material including silicon; and/or a thickness of each of the island structures is W, where W satisfies 20 μm≤W≤500 μm.

According to a second aspect, embodiments of the present disclosure provide a detection method for light-emitting elements, configured to detect the light-emitting elements through the detection apparatus in any of the aforementioned embodiments, and including following steps:
transmitting, according to a preset signal transmission rule, the first-type signal to the to-be-detected light-emitting elements through the first signal lines, and the second-type signal to the to-be-detected light-emitting elements through the second signal lines, where the to-be-detected light-emitting elements are respectively disposed in a plurality of detection regions of the substrate; the to-be-detected light-emitting elements each are connected to the first signal lines and the second signal lines; and the same first signal line is configured to be electrically connected to a plurality of to-be-detected light-emitting elements located in different detection regions; and
performing light emission identification on the to-be-detected light-emitting elements in each of the detection regions, identifying a to-be-detected light-emitting element with abnormal light emission, and determining the to-be-detected light-emitting element with abnormal light emission as a faulty element.

The embodiment of the present disclosure provides a detection apparatus and a detection method for light-emitting elements. By electrically connecting the same first signal line to a plurality of to-be-detected light-emitting elements located in different detection regions, the same first signal line can simultaneously transmit a first-type signal to the plurality of to-be-detected light-emitting elements. The design enables simultaneous detection on the plurality of light-emitting elements, thereby achieving batch detection and improving detection efficiency. Meanwhile, the design reduces the quantity of first signal lines and lowers the manufacturing cost of the detection apparatus.

### BRIEF DESCRIPTION OF THE DRAWINGS

To describe the technical solutions in the embodiments of the present disclosure, the following briefly describes the drawings required for the embodiments of the present disclosure. A person of ordinary skill in the art may still derive other drawings from these drawings without creative efforts.

FIG. 1 is a schematic structural diagram of a detection apparatus according to an embodiment of the present disclosure;

FIG. 2 is a schematic cross-sectional structural diagram taken along line A-A shown in FIG. 1;

FIG. 3 is a schematic structural diagram of a detection region in a detection apparatus according to an embodiment of the present disclosure;

FIG. 4 is a schematic structural diagram of a detection region in another detection apparatus according to an embodiment of the present disclosure;

FIG. 5 is a schematic structural diagram of still another detection apparatus according to an embodiment of the present disclosure;

FIG. 6 is a schematic structural diagram of still another detection apparatus according to an embodiment of the present disclosure;

FIG. 7 is a schematic diagram of a connection relationship between adjacent island structures in still another detection apparatus according to an embodiment of the present disclosure; and

FIG. 8 is a flowchart of a detection method for light-emitting elements according to an embodiment of the present disclosure.

### REFERENCE NUMERALS

1. substrate;
10. island structure;
20. connection portion; 21. main body portion; and 22. weakened portion;
30. to-be-detected element; and 31. light-emitting element;
C. detection region;
L1. first signal line; L2. second signal line; D1. first conductive portion; D2. second conductive portion; and Q. driving circuit; and
X. first direction; Y. second direction; and Z. thickness direction.

### DETAILED DESCRIPTION

Features of various aspects and exemplary embodiments of this application are described below in detail. To make the objectives, technical solutions, and advantages of this application clearer, this application is further described in detail below with reference to the accompanying drawings and embodiments. It should be understood that the embodiments described herein are merely used to explain this application, rather than to limit this application. A person skilled in the art can implement this application without some of these specific details. The following description of the embodiments is intended only to provide a better understanding of this application by illustrating examples of this application.

It should be noted that relational terms herein such as first and second are merely used to distinguish one entity or operation from another entity or operation without necessarily requiring or implying any actual such relationship or order between such entities or operations. In addition, terms “include”, “comprise”, or any other variations thereof are intended to cover a non-exclusive inclusion, such that a process, a method, an article, or a device that includes a series of elements not only includes those elements, but also includes other elements that are not explicitly listed, or also includes inherent elements of the process, the method, the article, or the device. Without more restrictions, the elements defined by the sentence “including . . . ” do not exclude the existence of other identical elements in a process, method, article, or device including the elements.

With the advancement of science and technology, the complexity of electrical devices gradually increases. Taking MicroLED display technology as an example, a MicroLED display apparatus is an advanced display technology based on micro light-emitting diodes (micro-LEDs). It refers to the process of addressing and massively transferring micro-LEDs as light-emitting elements to a circuit substrate, forming a self-emissive pixel array with ultra-small spacing. Through precise control of the brightness of each light-emitting element, image display with high brightness, high contrast, and high resolution can be achieved.

Each pixel in the MicroLED display apparatus can be addressed and individually driven to emit light, which can be regarded as a miniaturized version of an outdoor LED display, reducing the pixel pitch from millimeters to micrometers. Compared with existing display technology, MicroLED display apparatuses have advantages such as high brightness, low power consumption, ultra-high resolution, and color saturation. Meanwhile, they also offer advantages such as transparency, flexibility, stretchability, and deep integration with micro-sensors, which break through the traditional display application scenarios, making them a revolutionary display technology in the future.

MicroLED display apparatuses have attracted significant attention and substantial investment from major consumer electronics and optoelectronics companies worldwide, such as Apple, Huawei, Google, Samsung, San′an Optoelectronics, TCL China Star Optoelectronics Technology (TCL CSOT), Osram, and Beijing Oriental Electronics (BOE). They have enormous market potential and influence. The total investment in China's new display industry exceeds 1.3 trillion yuan, making China the largest display panel production base in the world. In particular, MicroLED display technology is a mainstream direction for next-generation display technology to be prioritized and supported during the “14th Five-Year Plan” period. However, the development of MicroLED display technology is still in its early stages. To produce the MicroLED display apparatus, a large quantity of light-emitting elements must be transferred to a backplane with driving circuits in a batchwise, rapid, efficient, and low-cost manner, a process known as “mass transfer”. Currently, the industry has invested significant effort in mass transfer, resulting in various technical approaches such as electrostatic force transfer, laser-assisted transfer, elastomer stamp transfer, and magnetic force transfer, which are becoming increasingly mature.

Display applications require extremely high pixel yield, needing to reach 99.9999% or even higher. However, due to limitations in manufacturing processes, the yield of manufactured light-emitting elements falls far short of this requirement. Therefore, in addition to mass transfer, the yield issue of light-emitting elements must also be addressed, making efficient mass detection on light-emitting elements an unavoidable challenge.

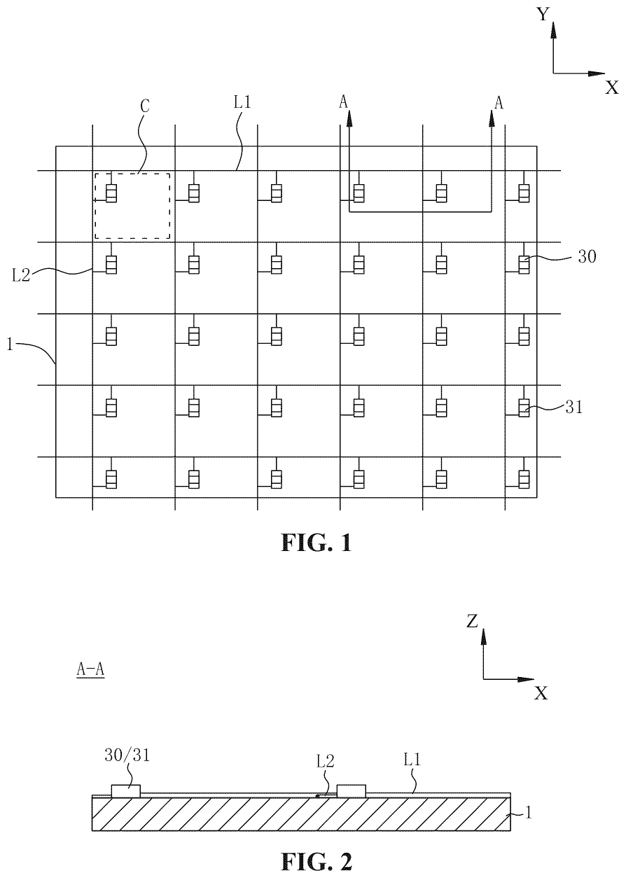

In view of the foregoing problems, in one aspect, referring to FIG. 1 and FIG. 2, an embodiment of the present disclosure provides a detection apparatus. The detection apparatus includes a substrate 1, a plurality of first signal lines L1, and a plurality of second signal lines L2. The plurality of first signal lines L1 are disposed on the substrate 1 and extend along a first direction X. The first signal lines L1 are configured to transmit a first-type signal to to-be-detected elements 30. The plurality of second signal lines L2 are disposed on the substrate 1 and extend along a second direction Y. The first direction X intersects the second direction Y. The second signal lines L2 are configured to transmit a second-type signal to the to-be-detected elements 30. At least two adjacent ones of the first signal lines L1 and at least two adjacent ones of the second signal lines L2 collectively define at least one detection region C on the substrate 1 for accommodating the to-be-detected elements 30. The same first signal line L1 can be electrically connected to a plurality of to-be-detected elements 30 located in different detection regions C.

The detection apparatus is configured to perform batch or individual detection on the to-be-detected elements 30. Each of the to-be-detected elements 30 includes, but is not limited to, a light-emitting element 31 and a driving control element. For convenience of description, in the subsequent description in the embodiment of the present disclosure, the to-be-detected element 30 is a light-emitting element 31. The light-emitting element 31 includes, but is not limited to, a micro-LED in a MicroLED display apparatus.

The substrate 1 is a main part of the detection apparatus. The substrate 1 may be a rigid substrate 1, which means that the substrate 1 cannot be bent or deformed. Alternatively, the substrate 1 may be a flexible substrate 1, which means that the substrate 1 can be bent or deformed to a certain extent.

The first signal lines L1 and the second signal lines L2 are disposed on the substrate 1. The first signal lines L1 may be fully located on a surface of the substrate 1 in a thickness direction Z, may be fully located inside the substrate 1, and may be partially located on the surface of the substrate 1 in the thickness direction Z and partially located inside the substrate 1. The same design applies to the second signal lines L2, which is not limited in the embodiment of the present disclosure.

The first signal line L1 and the second signal line L2 are electrically connected to the light-emitting element 31. The first signal line L1 is configured to transmit the first-type signal to the light-emitting element 31. The second signal line L2 is configured to transmit the second-type signal to the light-emitting element 31. The first-type signal and the second-type signal are different. For example, one of the first-type signal and the second-type signal is a data signal, and the other is a scan signal. These two types of signals work together to control an operating state of the light-emitting element 31, such as to cause the light-emitting element 31 to emit light or stop emitting light.

The material of the first signal line L1 is not limited in the embodiment of the present disclosure. For example, the first signal line L1 may include a metal material, such as gold, silver, aluminum, and titanium. Alternatively, the first signal line L1 may include a semiconductor material, such as indium tin oxide (ITO).

When the first signal line L1 and the second signal line L2 simultaneously transmit the first-type signal and the second-type signal respectively to the same light-emitting element 31, if the light-emitting element 31 emits light normally, it indicates that the light-emitting element 31 is a good product. If the light-emitting element 31 does not emit light or emits light abnormally, it indicates that the light-emitting element 31 is faulty and needs to be repaired or discarded.

The first signal line L1 extends along the first direction X, and the second signal line L2 extends along the second direction Y. The first direction X intersects the second direction Y, which means that extension directions of the first signal line L1 and the second signal line L2 are not parallel. An angle between the first direction X and the second direction Y is not limited in the embodiment of the present disclosure. The angle includes, but is not limited to, 30°, 60°, 90°, 120°, and 150°. Optionally, the first direction X is perpendicular to the second direction Y, which means that the angle between the first direction X and the second direction Y is 90°.

It should be noted that since the extension directions of the first signal line L1 and the second signal line L2 are different, projections of the first signal line L1 and the second signal line L2 in the thickness direction Z of the substrate 1 will overlap. To reduce the risk of signal crosstalk between the first-type signal and the second-type signal, the first signal line L1 and the second signal line L2 need to be insulated from each other. As an example, an insulating material is disposed between the first signal line and the second signal line at an overlap position. Alternatively, one of the first signal line L1 and the second signal line L2 is disposed on the surface of the substrate 1, and the other is disposed inside the substrate 1, thereby improving the insulation reliability between the first signal line and the second signal line.

On this basis, the plurality of first signal lines L1 and the plurality of second signal lines L2 define a plurality of detection regions C. If the first direction X is perpendicular to the second direction Y, a projection of the detection region C in the thickness direction Z is a rectangle. If the first direction X is not perpendicular to the second direction Y, the projection of the detection region C in the thickness direction Z is a parallelogram other than a rectangle. One of the first direction X and the second direction Y can serve as a row direction for the arrangement of the plurality of detection regions C, and the other can serve as a column direction for the arrangement of the plurality of detection regions. For convenience of description, in the subsequent description in the embodiment of the present disclosure, the first direction X serves as the row direction and the second direction Y serves as the column direction as an example.

The light-emitting element 31 can be disposed in the detection region C. Two sides of the light-emitting element 31 within the detection region C in the second direction Y are provided with two adjacent first signal lines L1. The light-emitting element 31 can be electrically connected to any one of the two first signal lines L1. Similarly, two sides of the light-emitting element 31 within the detection region C in the first direction X are provided with two adjacent second signal lines L2. The light-emitting element 31 can be electrically connected to any one of the two second signal lines L2. A single detection region C may be provided with only one light-emitting element 31 or may be provided with a plurality of light-emitting elements 31, which is not limited in the embodiment of the present disclosure.

It should be noted that it is impossible for two first signal lines to define a detection region C on a side of an outermost first signal line L1 away from other first signal lines L1. However, a light-emitting element 31 can still be disposed on the side of the outermost first signal line L1 away from the other first signal lines L1 and electrically connected to the first signal line L1 closest to it, i.e., the outermost first signal line L1. Similarly, it is impossible for two second signal lines to define a detection region C on a side of an outermost second signal line L2 away from other second signal lines L2. However, a light-emitting element 31 can still be disposed on the side of the outermost second signal line L2 away from the other second signal lines L2 and electrically connected to the second signal line L2 closest to it, i.e., the outermost second signal line L2. In other words, some light-emitting elements 31 may not be disposed in the detection regions C.

Furthermore, in the embodiment of the present disclosure, the same first signal line L1 is configured to be electrically connected to a plurality of light-emitting elements 31 located in different detection regions C, enabling the same first signal line L1 to simultaneously transmit the first-type signal to the plurality of light-emitting elements 31. The design enables simultaneous detection on a plurality of light-emitting elements 31, achieving a batch detection effect and improving detection efficiency. Meanwhile, the design reduces the quantity of first signal lines L1 and lowers the manufacturing cost of the detection apparatus.

In some embodiments, as shown in FIG. 1 and FIG. 2, the same second signal line L2 is configured to be electrically connected to a plurality of to-be-detected elements 30 located in different detection regions C.

The same second signal line L2 is electrically connected to a plurality of light-emitting elements 31 located in different detection regions C, enabling the same second signal line L2 to simultaneously transmit the second-type signal to the plurality of light-emitting elements 31. The design enables simultaneous detection on a plurality of light-emitting elements 31, achieving a batch detection effect and improving detection efficiency. Meanwhile, the design reduces the quantity of second signal lines L2 and lowers the manufacturing cost of the detection apparatus.

Furthermore, different detection modes of the detection apparatus are achieved by controlling different first signal lines L1 and second signal lines L2 to transmit specific signals respectively. Specifically, when a single first signal line L1 and a single second signal line L2 are controlled to transmit specific signals respectively, light emission detection on a specific light-emitting element 31, i.e., a single-point detection mode, is achieved. When all first signal lines L1 and all second signal lines L2 are controlled to transmit specific signals respectively, light emission detection on all light-emitting elements 31, i.e., a global detection mode, is achieved. When some first signal lines L1 and some second signal lines L2 are controlled to transmit specific signals respectively, light emission detection on local light-emitting elements 31, i.e., a local detection mode, is achieved. When a single first signal line L1 and all second signal lines L2 are controlled to transmit specific signals respectively, light emission detection on a single row of light-emitting elements 31 is achieved. When a single second signal line L2 and all first signal lines L1 are controlled to transmit specific signals respectively, light emission detection on a single column of light-emitting elements 31 is achieved. This enables a row/column detection mode.

It should be noted that the types of specific signals transmitted by the first signal line L1 and the second signal line L2 are not limited in the embodiment of the present disclosure. For example, the light-emitting element 31 electrically connected to the first signal line L1 and the second signal line L2 operates only when the first signal line transmits a high-level signal and the second signal line transmits a low-level signal. That is, when the first signal line L1 does not transmit a signal or transmits a low-level signal, the light-emitting element 31 electrically connected to the first signal line cannot be driven to work. When the second signal line L2 does not transmit a signal or transmits a high-level signal, the light-emitting element 31 electrically connected to the second signal line cannot be driven to work.

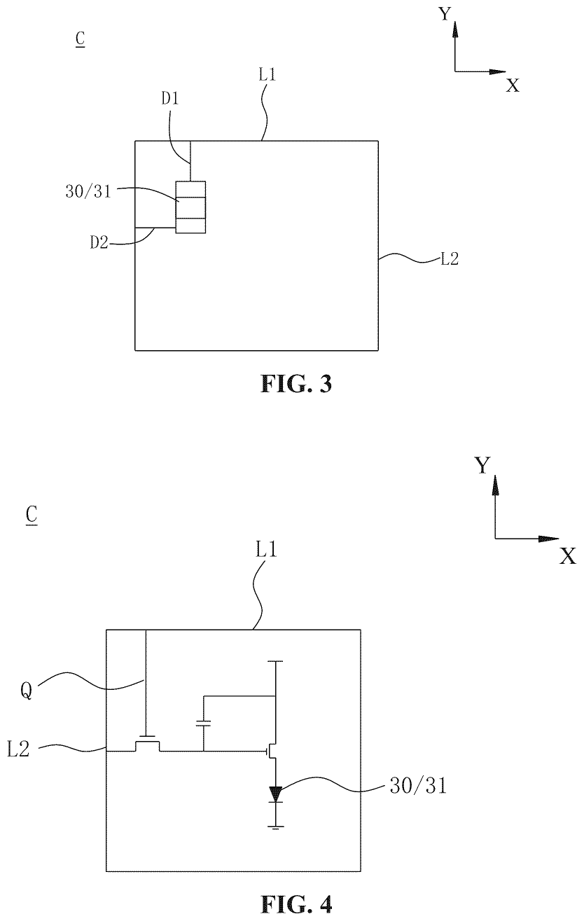

In some embodiments, referring to FIG. 3, the detection apparatus further includes a first conductive portion D1 located in the detection region C and connected to the first signal line L1. The first signal line is connected to the to-be-detected element 30 through the first conductive portion D1.

The first conductive portion D1 is configured to connect the light-emitting element 31 and the first signal line L1. The first conductive portion D1 can be in direct contact with the light-emitting element 31 and the first signal line L1 respectively to achieve a signal transmission function, thereby achieving passive driving of the light-emitting element 31.

As can be known from the foregoing, the first signal line L1 may be located on the surface of the substrate 1 in the thickness direction Z, and may be located inside the substrate 1. When the first signal line L1 is located on the surface of the substrate 1 in the thickness direction Z, the first conductive portion D1 can also be located on the surface of the substrate 1 in the thickness direction Z. When the first signal line L1 is located inside the substrate 1, the first conductive portion D1 can be disposed in a via hole of the substrate 1, thereby electrically connecting the first signal line L1 and the first conductive portion D1 through the via hole.

Similarly, in other embodiments, the detection apparatus further includes a second conductive portion D2 located in the detection region C and connected to the second signal line L2. The second signal line is connected to the to-be-detected element 30 through the second conductive portion D2. The second conductive portion D2 is configured to connect the light-emitting element 31 and the second signal line L2. The second conductive portion D2 can be in direct contact with the light-emitting element 31 and the second signal line L2 respectively to achieve a signal transmission function, thereby achieving passive driving of the light-emitting element 31.

It should be noted that when a specific light-emitting element 31 is transferred, the first conductive portion D1 and the second conductive portion D2 electrically connected to the specific light-emitting element are transferred together with the light-emitting element 31.

In some embodiments, referring to FIG. 4, the detection apparatus further includes a driving circuit Q disposed in the detection region C. The driving circuit Q is connected to the to-be-detected element 30. The first signal line L1 and the second signal line L2 are connected to the driving circuit to control the turn-on or turn-off of the driving circuit Q, thereby controlling an operating state of the to-be-detected element 30.

The driving circuit Q and the light-emitting element 31 both are disposed in the detection region C. The structural form of the driving circuit Q is not limited in the embodiment of the present disclosure. For example, the driving circuit Q may include a driving transistor and a capacitor. The driving circuit Q can be in circuit forms such as 2T1C (2 Transistor 1 Capacitor), 7T1C (7 Transistor 1 Capacitor), or 8T1C (8 Transistor 1 Capacitor). Alternatively, the driving circuit Q may also include a complementary metal oxide semiconductor (CMOS).

The first signal line L1 and the second signal line L2 both are connected to the driving circuit Q, and the driving circuit Q is connected to the light-emitting element 31, thereby enabling active driving of the light-emitting element 31. The driving circuit Q can be formed by a plurality of stacked film layer structures within the substrate 1. For example, the substrate 1 may include an active layer, a gate layer, and a source-drain layer. The gate layer is provided with a gate, the active layer is provided with an active structure, and the source-drain layer is provided with a source and a drain. The source is connected to a source region in the active structure, and the drain is connected to a drain region in the active structure, thereby forming the driving transistor in the driving circuit Q.

It should be noted that when a specific light-emitting element 31 is transferred, the driving circuit Q is transferred together with the light-emitting element 31 to the target substrate, thereby forming a display apparatus.

In some embodiments, a single detection region includes a space for accommodating a plurality of to-be-detected elements. The plurality of first signal lines include at least one of first signal lines connected in one-to-one correspondence to at least one of the to-be-detected elements in the same detection region and/or a first signal line connected to at least one of the to-be-detected elements in the same detection region. The plurality of second signal lines include at least one of second signal lines connected in one-to-one correspondence to at least one of the to-be-detected elements in the same detection region and/or a second signal line connected to at least one of the to-be-detected elements in the same detection region.

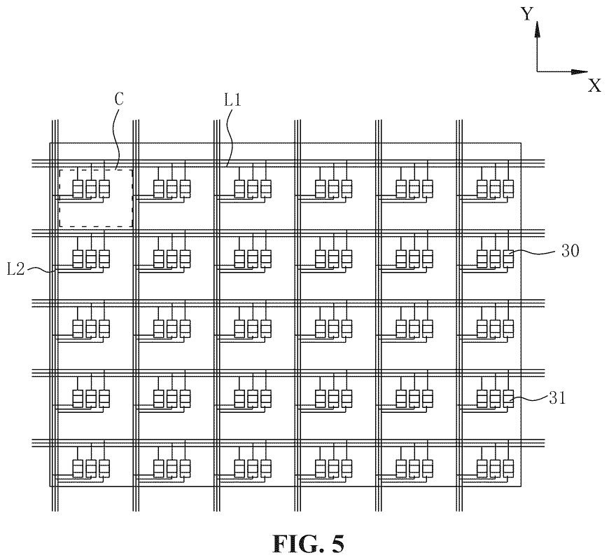

In an embodiment, referring to FIG. 5, a single detection region C accommodates a plurality of to-be-detected elements 30. The plurality of first signal lines L1 only include some first signal lines L1 electrically connected in one-to-one correspondence to the plurality of light-emitting elements 31 located in the same detection region C. The plurality of second signal lines L2 only include some second signal lines L2 electrically connected in one-to-one correspondence to the plurality of light-emitting elements 31 located in the same detection region C. Optionally, in addition to the foregoing case, the plurality of first signal lines L1 may further include at least one of first signal lines connected in one-to-one correspondence to at least one of the to-be-detected elements located in the same detection region and/or a first signal line connected to at least one of the to-be-detected elements located in the same detection region. The plurality of second signal lines L2 may further include at least one of second signal lines connected in one-to-one correspondence to at least one of the to-be-detected elements located in the same detection region and/or a second signal line connected to at least one of the to-be-detected elements located in the same detection region.

A single detection region C can be provided with a plurality of light-emitting elements 31 to reduce the quantity of detection regions C, thereby reducing the size of the detection apparatus to some extent. Alternatively, more light-emitting elements 31 can be arranged in a detection apparatus of a specific size to improve detection efficiency. The number and colors of the light-emitting elements 31 in a single detection region C are not limited in the embodiment of the present disclosure. For example, a single detection region C is provided with three light-emitting elements 31 of different colors, and the three light-emitting elements 31 of different colors can be configured to form a pixel repeating unit.

The arrangement of different light-emitting elements 31 in a single detection region C is not limited in the embodiment of the present disclosure. The different light-emitting elements 31 in the single detection region C may be arranged side by side along the same direction or may be arranged side by side along different directions. The connection method of different light-emitting elements 31 in a single detection region C is not limited in the embodiment of the present disclosure.

In some embodiments, the arrangement direction of the plurality of to-be-detected elements 30 located in the same detection region C is the same as the arrangement direction of the plurality of correspondingly connected first signal lines L1.

The plurality of light-emitting elements 31 located in the same detection region C are arranged side by side along a single direction and are connected to different first signal lines L1. On this basis, in the embodiment of the present disclosure, the arrangement direction of the plurality of light-emitting elements 31 in the same detection region C is the same as the arrangement direction of the first signal lines L1. For example, if the plurality of first signal lines L1 are arranged side by side along the second direction Y, the plurality of light-emitting elements 31 located in the same detection region C are also arranged side by side along the second direction Y.

The design unifies the arrangement of the first signal lines L1 with the arrangement of the plurality of light-emitting elements 31, which reduces the connection difficulty between the plurality of light-emitting elements 31 in the single detection region C and the first signal lines L1. Similarly, in other embodiments, the arrangement direction of the plurality of light-emitting elements 31 located in the same detection region C is the same as the arrangement direction of the plurality of correspondingly connected second signal lines L2.

In some embodiments, the arrangement order of the plurality of to-be-detected elements 30 located in the same detection region C is the same as the arrangement order of the plurality of correspondingly connected first signal lines L1. Specifically, referring to the drawings, the plurality of light-emitting elements 31 in the same detection region C are arranged sequentially from top to bottom along the second direction Y, and the plurality of first signal lines L1 connected to the light-emitting elements are also arranged sequentially from top to bottom along the second direction Y.

Compared to a scheme where the arrangement order of the plurality of light-emitting elements 31 is different from the arrangement order of the corresponding first signal lines L1, the embodiment of the present disclosure reduces the difference in trace lengths between different light-emitting elements 31 and the corresponding first signal lines L1. This eliminates the need to design overly long trace structures for specific light-emitting elements 31 further reducing the connection difficulty between the first signal lines L1 and the light-emitting elements 31.

Similarly, in other embodiments, as shown in FIG. 5, the arrangement direction and the arrangement order of the plurality of to-be-detected elements 30 located in the same detection region C are the same as those of the plurality of correspondingly connected second signal lines L2.

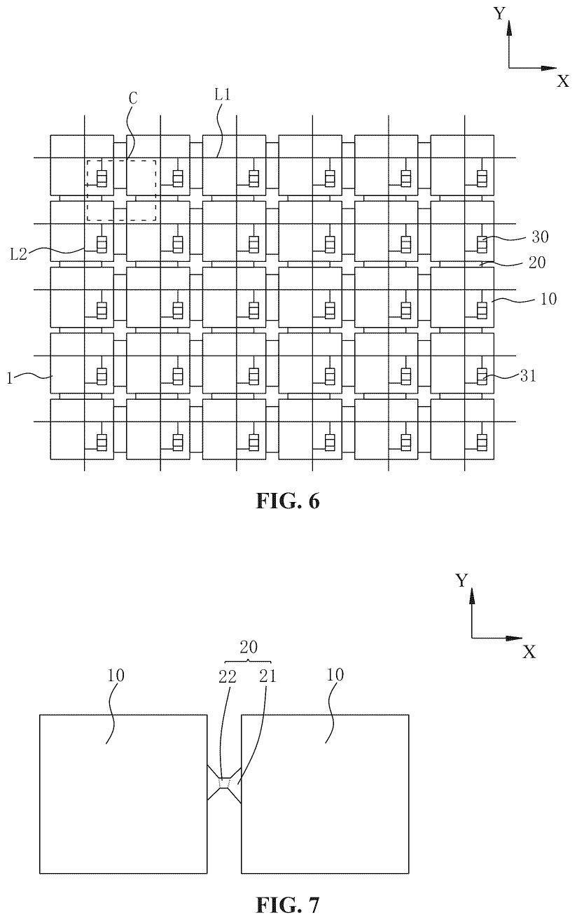

In some embodiments, referring to FIG. 6, the substrate 1 includes a plurality of island structures 10 spaced apart and connection portions 20 for connecting adjacent island structures 10. The island structures 10 each are configured to provide a space for accommodating a plurality of to-be-detected elements 30.

The plurality of island structures 10 may be arranged side by side along a single direction or may be arranged side by side along different directions. For example, the plurality of island structures 10 are arrayed along the first direction X and the second direction Y, respectively. The size and shape of the island structures 10 are not limited in the embodiment of the present disclosure. For example, projections of the island structures 10 in the thickness direction Z may be square, circular, or polygonal.

The light-emitting element 31 is disposed on the island structure 10, and the light-emitting element 31 is located in the detection region C. The relative positional relationship between the island structure 10 and the detection region C is not limited in the embodiment of the present disclosure. For example, the projection of the island structure 10 in the thickness direction Z may be located in the projection of the detection region C in the thickness direction Z. Alternatively, the projection of the detection region C in the thickness direction Z may be located in the projection of the island structure 10 in the thickness direction Z. Alternatively, the projection of the detection region C in the thickness direction Z may partially overlap with the projection of the island structure 10 in the thickness direction Z.

Furthermore, each island structure 10 may be provided with only one light-emitting element 31, or may be provided with a plurality of light-emitting elements 31, which is not limited in the embodiment of the present disclosure.

The connection portion 20 is configured to connect adjacent island structures 10. The specific structural form of the connection portion 20 is not limited in the embodiment of the present disclosure. Optionally, the connection portion 20 may be integrated, i.e., formed simultaneously, with the island structure 10, and the connection portion 20 has a strength lower than that of the island structure 10.

It should be noted that for the first signal line L1, the first signal line L1 may be disposed on the connection portion 20, which means that the projection of the first signal line L1 in the thickness direction Z overlaps with a projection of the connection portion 20 in the thickness direction Z. Alternatively, the first signal line L1 may not be disposed on the connection portion 20, which means that the projection of the first signal line L1 in the thickness direction Z does not overlap with the projection of the connection portion 20 in the thickness direction Z. The same design applies to the second signal line L2.

The detection apparatus provided by the embodiment of the present disclosure is configured not only to detect yield but also to achieve the transfer of the light-emitting element 31. Specifically, after the detection is completed, when the connection portion 20 is actuated, the island structure 10 corresponding to the good light-emitting element 31 is separated from other island structures 10. Regarding the actuation, the connection portion 20 is moved or activated to a certain state, causing the adjacent island structures 10 to separate. The movement of the connection portion 20 may include, but is not limited to, breaking, fracturing, tearing, or opening of at least a part of the connection portion 20. Furthermore, it may be breaking, fracturing, tearing, or opening of a connection position between the connection portion 20 and the island structure 10.

When a single island structure 10 is separated from the adjacent island structure 10, the light-emitting element 31 located on the single island structure is transferred. Meanwhile, a partial structure of the first signal line L1 corresponding to the single island structure 10 fractures and is transferred together with the light-emitting element 31, and a partial structure of the second signal line L2 corresponding to the single island structure 10 fractures and is transferred together with the light-emitting element 31. That is, when the light-emitting element 31 is transferred, the light-emitting element 31, the island structure 10 corresponding to the light-emitting element 31, the partial structure of the first signal line L1 electrically connected to the light-emitting element 31, and the partial structure of the second signal line L2 electrically connected to the light-emitting element 31 are transferred together to the corresponding target substrate. Furthermore, when the light-emitting element 31 is connected to the driving circuit, the driving circuit is transferred together with the light-emitting element 31 to the target substrate.

In related art, typically, only the light-emitting element 31 is transferred to the corresponding target substrate. This transfer method is typically limited by the structural design of the target substrate, i.e., the array substrate 1, such that the light-emitting element 31 can only be transferred to a specific position of a specific target substrate. However, in the embodiment of the present disclosure, since the partial structure of the first signal line L1, the partial structure of the second signal line L2, and the driving circuit are transferred together with the light-emitting element 31 to the target substrate, the light-emitting element 31 is no longer limited by the routing layout of the array substrate 1. Moreover, the existence of the island structure 10 reduces the dependence of the light-emitting element 31 on the film layer structure of the array substrate 1. Thus, the light-emitting element can be transferred to different types of target substrates, and even when the target substrate is flexible or partially flexible, it can be configured to manufacture a curved display or flexible display module, resulting in strong versatility.

In some embodiments, at least some of the island structures 10 are arranged side by side in the extension direction of the first signal line L1.

A single first signal line L1 is disposed on a plurality of island structures 10. On this basis, setting the side-by-side arrangement direction of at least some island structures 10 to be the extension direction of the first signal line L1 facilitates the layout and extension of the first signal line L1 on the plurality of island structures 10. The design reduces the wiring difficulty of the first signal line L1 and improves the reliability of the relative position between the island structure 10 and the first signal line L1.

Similarly, in other embodiments, at least some of the island structures 10 are arranged side by side in the extension direction of the second signal line L2. Optionally, a plurality of island structures 10 are arranged side by side along the first direction X and the second direction Y, respectively. The first signal line L1 extends along the first direction X and is disposed on a plurality of island structures 10 arranged side by side in the first direction X. The second signal line L2 extends along the second direction Y and is disposed on a plurality of island structures 10 arranged side by side in the second direction Y.

In some embodiments, referring to FIG. 7, a weakened portion 22 is disposed on the connection portion 20. A structural strength of the weakened portion 22 is less than a structural strength at other positions on the connection portion 20, so the weakened portion serves as a disconnection position for disconnecting the connected island structures.

The “structural strength” mentioned in the embodiment of the present disclosure refers to a fracture resistance of the corresponding structure. A higher structural strength makes the structure less likely to fracture under external force, and a lower structural strength makes the structure more likely to fracture under external force. Therefore, compared to other structures on the connection portion 20, the weakened portion 22 is more prone to fracture and damage under external force.

The material, shape, size and other parameters of the weakened portion 22 are not limited in the embodiment of the present disclosure, as long as the structural strength of the weakened portion 22 is less than the structural strength at other positions on the connection portion 20. For example, the weakened portion 22 may be made of the same material as and formed integrally with other structures on the connection portion 20. In this case, the structural strength at the position of the connection portion 20 is reduced through a process, thereby forming the weakened portion 22. Alternatively, the material of the weakened portion 22 may be different from the material of other structures on the connection portion 20. In this case, the weakened portion 22 and the other structures on the connection portion 20 are formed separately and then connected and fixed through a connection method including, but not limited to, bonding and welding.

In the embodiment of the present disclosure, providing the weakened portion 22 on the connection portion 20 ensures that, when the light-emitting element 31 is transferred, the connection portion 20 is quickly actuated at the weakened portion 22 to separate the adjacent island structures 10, thereby meeting the transfer need.

In some embodiments, as shown in FIG. 7, the connection portion 20 includes the weakened portion 22 and a main body portion 21. A width of the weakened portion 22 is less than a width of the main body portion 21.

Depending on the position of the connection portion 20, the width direction of the weakened portion 22 varies. For example, a plurality of island structures 10 are arranged side by side along the first direction X and the second direction Y, respectively. For the connection portion 20 located between two adjacent island structures 10 in the first direction X, the width direction of both the weakened portion 22 and the main body portion 21 is the second direction Y. For the connection portion 20 located between two adjacent island structures 10 in the second direction Y, the width direction of both the weakened portion 22 and the main body portion 21 is the first direction X.

In the embodiment of the present disclosure, by controlling the width of the weakened portion 22 to be less than the width of the main body portion 21, the structural strength of the weakened portion 22 is less than the structural strength of the main body portion 21. This ensures that the connection portion 20 is quickly actuated at the weakened portion 22 to separate the adjacent island structures 10, thereby meeting the transfer need.

In other embodiments, a thickness of the weakened portion 22 is less than a thickness of the main body portion 21. This means that the size of the weakened portion 22 in the thickness direction Z is less than the size of the main body portion 21 in the thickness direction Z.

Similar to the foregoing embodiment, by controlling the thickness of the weakened portion 22 to be less than the thickness of the main body portion 21, the structural strength of the weakened portion 22 is less than the structural strength of the main body portion 21. This ensures that the connection portion 20 is quickly actuated at the weakened portion 22 to separate the adjacent island structures 10, thereby meeting the transfer need.

In some embodiments, in a direction from the main body portion 21 to the weakened portion 22, the width of the connection portion 20 gradually decreases. In other words, the width of the connection portion 20 is smaller at a position closer to the weakened portion 22 and is larger at a position farther away from the weakened portion 22. For example, the projection of the connection portion 20 in the thickness direction Z is a butterfly-like structure, with a narrowest position forming the weakened portion 22.

This design further increases the probability of actuation occurring at the weakened portion 22, thereby achieving precise control over the actuation position in the connection portion 20. Thus, the impact of the actuation of the connection portion 20 on the island structure 10 is reduced, improving transfer accuracy and reliability.

Similarly, in other embodiments, in the direction from the main body portion 21 to the weakened portion 22, a thickness of the connection portion 20 gradually decreases.

In some embodiments, the island structure 10 and the connection portion 20 are an integral structure, and the thickness of the connection portion 20 is less than a thickness of the island structure 10.

The island structure 10 and the connection portion 20 are made of the same material and can be formed simultaneously. On this basis, the embodiment of the present disclosure sets the thickness of the connection portion 20 to be less than that of the island structure 10. The design increases the probability of actuation occurring at the connection portion 20 and reduces the risk of damage and deformation of the island structure 10 during the transfer process, thereby improving transfer reliability.

It should be noted that the thickness of the island structure 10 mentioned in the embodiment of the present disclosure refers to an average thickness of the island structure 10, and the thickness of the connection portion 20 refers to an average thickness of the connection portion 20. The thickness at some positions of the connection portion 20 may also be greater than the thickness at some positions of the island structure 10.

In other embodiments, the island structure 10 and the connection portion 20 form an integrated structure, and the width of the connection portion 20 is less than the width of the island structure 10.

In some embodiments, the connection portions each include a base and a metal wiring layer stacked on a side of the base; and/or
the connection portions each include highly doped polycrystalline silicon.

The plurality of first signal lines are respectively disposed on the connection portions; and/or
the plurality of second signal lines are respectively disposed on the connection portions.

In some embodiments, the island structure is made of a material including silicon; and/or
a thickness of each of the island structures is W, where W satisfies 20 μm≤W≤500 μm.

The formation method of the island structure 10 and the connection portion 20 is not limited in the embodiment of the present disclosure. For example, the island structure 10 and the connection portion 20 are formed by a deep reactive ion etching (DRIE) process.

Specifically, first, a silicon dioxide (SiO₂) film is deposited on a side of a silicon-based substrate in the thickness direction. A layer of photoresist is applied to a side of the SiO₂ film away from the silicon-based substrate, and selective exposure, development, and hard baking are performed to form a mask layer made of photoresist. A region covered by the photoresist forms a first area, and a region not covered by the photoresist forms a second area. Hydrofluoric acid is applied to perform wet etching on the SiO2 film in the second area not covered by the photoresist. After the SiO2 film in the second area is completely etched, the silicon-based substrate is placed in acetone to completely remove the photoresist. The second area of the silicon-based substrate not covered by the SiO2 film is etched by DRIE to reduce the silicon-based material in the second area, thereby forming the connection portion. The silicon-based substrate is immersed in a hydrofluoric acid solution to completely remove the SiO2 film, thereby forming the island structure and the connection portion in the transfer substrate.

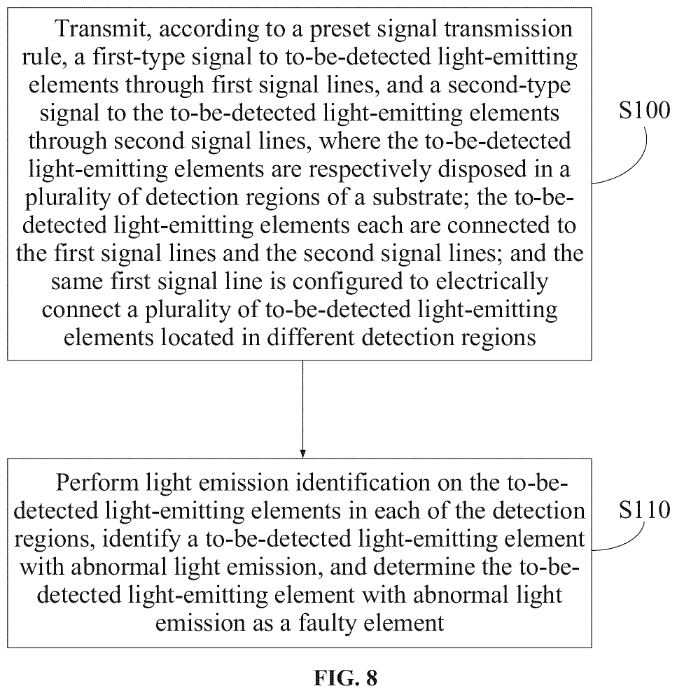

In a second aspect, referring to FIG. 8, an embodiment of the present disclosure provides a detection method for light-emitting elements. The detection method is configured to detect the light-emitting elements through the detection apparatus according to any of the preceding implementations, and includes following steps.

S100: According to a preset signal transmission rule, the first-type signal is transmitted to the to-be-detected light-emitting elements through the first signal lines, and the second-type signal is transmitted to the to-be-detected light-emitting elements through the second signal lines. The to-be-detected light-emitting elements are respectively disposed in a plurality of detection regions of the substrate. The to-be-detected light-emitting elements each are connected to the first signal lines and the second signal lines. The same first signal line is electrically connected to a plurality of to-be-detected light-emitting elements located in different detection regions.

In step S100, each to-be-detected light-emitting element is connected to a first signal line and a second signal line. The first signal line and the second signal line define a detection region for accommodating the light-emitting element. The first signal line and the second signal line jointly control the operation of the light-emitting element by transmitting the first-type signal and the second-type signal. When the to-be-detected light-emitting element receives the specific signals transmitted by the corresponding first signal line and second signal line respectively, if the to-be-detected light-emitting element emits light normally, it indicates that the light-emitting element is a good product. If the to-be-detected light-emitting element does not emit light or emits light abnormally, it indicates that the light-emitting element is faulty. When the to-be-detected light-emitting element is determined as a faulty element, it needs to be repaired or discarded, thereby completing the detection on the light-emitting element.

S110: Light emission identification is performed on the to-be-detected light-emitting elements in each of the detection regions. A to-be-detected light-emitting element with abnormal light emission is identified, and the to-be-detected light-emitting element with abnormal light emission is determined as a faulty element.

In step S100, according to the preset signal transmission rule, a first signal line is turned on to transmit the first-type signal and a plurality of second signal lines are turned on to transmit the second-type signal. The design enables simultaneous detection on a plurality of light-emitting elements, achieving a batch detection effect, and improving detection efficiency.

Furthermore, the preset signal transmission rule includes controlling different first signal lines and second signal lines to transmit specific signals respectively to achieve different detection modes of the detection apparatus. Specifically, when the preset signal transmission rule is to control a single first signal line and a single second signal line to transmit specific signals respectively, light emission detection on a specific to-be-detected element, i.e., a single-point detection mode, can be achieved. When the preset signal transmission rule is to control all first signal lines and all second signal lines to transmit specific signals respectively, light emission detection on all to-be-detected elements, i.e., a global detection mode, can be achieved. When the preset signal transmission rule is to control some first signal lines and some second signal lines to transmit specific signals respectively, light emission detection on local to-be-detected elements, i.e., a local detection mode, can be achieved. The plurality of first signal lines and the plurality of second signal lines all have corresponding numbers. The quantity and serial numbers of the selected partial first signal lines and partial second signal lines to be controlled in the preset signal transmission rule can be custom-set. Furthermore, when the preset signal transmission rule is to control a single first signal line and all second signal lines to transmit specific signals respectively, light emission detection on a single row of to-be-detected elements can be achieved. When the preset signal transmission rule is to control a single second signal line and all first signal lines to transmit specific signals respectively, light emission detection on a single column of to-be-detected elements can be achieved. This enables a row/column detection mode. Optionally, the preset signal transmission rule further includes setting information such as signal transmission time, signal transmission frequency, and signal type of the first-type signal transmitted to the to-be-detected light-emitting elements through the first signal lines. It also includes setting information such as signal transmission time, signal transmission frequency, and signal type of the second-type signal transmitted to the to-be-detected light-emitting elements through the second signal lines.

Specifically, in step S110, a device executing the detection method for the light-emitting elements may be an integrated device including a processor and including or connected to various signal transmission devices, such as a personal computer (PC), a tablet, a server, or a cloud platform. The various signal transmission devices are connected to the plurality of first signal lines and the plurality of second signal lines in the detection apparatus of the first aspect.

In an embodiment, the method for performing light emission identification on the to-be-detected light-emitting elements in each of the detection regions specifically includes following steps. After the first-type signal is transmitted to the to-be-detected light-emitting elements through the first signal lines and the second-type signal is transmitted to the to-be-detected elements through the second signal lines, images of the various detection regions in the detection apparatus are acquired. Image identification is performed on the to-be-detected light-emitting elements in the images of the various detection regions to identify to-be-detected light-emitting elements with normal light emission and to-be-detected elements with abnormal light emission in the images. In this way, to-be-detected light-emitting elements with abnormal light emission in each of the detection regions are identified according to identification results of the images of the various detection regions.

Specifically, abnormal light emission of the light-emitting elements may include brightness or color temperature not reaching a preset threshold, and no light emission, etc. Optionally, a pre-trained image identification neural network model may be adopted to perform light emission identification on the images of the various detection regions. A sample dataset for training the model may include image data of light-emitting elements with brightness not reaching a preset threshold, color temperature not reaching a preset threshold, and/or no light emission. By training the image identification neural network model through the sample dataset, a light emission identification model capable of identifying light-emitting elements with abnormal light emission is obtained.

Although the implementation manners of the present disclosure are described as above, the contents of the present disclosure are only to facilitate the understanding of the present disclosure, but should not be construed as limiting the present disclosure. It should be noted that for a person of ordinary skill in the art, several improvements and modifications may further be made without departing from spirits and scope of the present disclosure. Improvements and modifications in the implementation manners and details can be made, but the protection scope of the present disclosure shall still be governed by the scope defined in the attached claim.

The foregoing descriptions are merely specific implementations of this application. A person skilled in the art can clearly understand that, for convenience and brevity of description, reference may be made to corresponding processes in the foregoing method embodiments for the above-described connections. Details are not described herein again. It should be understood that the protection scope of this application is not limited herein. Any equivalent modification or replacement readily figured out by a person skilled in the art within the technical scope disclosed in the present disclosure shall fall within the protection scope of the present disclosure.

1. A detection apparatus, comprising:
a substrate;
a plurality of first signal lines, wherein the first signal lines are disposed on the substrate and extend along a first direction; and the first signal lines are configured to transmit a first-type signal to to-be-detected elements; and
a plurality of second signal lines, wherein the second signal lines are disposed on the substrate and extend along a second direction; the first direction intersects the second direction; and the second signal lines are configured to transmit a second-type signal to the to-be-detected elements;
wherein at least two adjacent ones of the first signal lines and at least two adjacent ones of the second signal lines jointly define at least one detection region on the substrate for accommodating the to-be-detected elements; and the same first signal line is configured to be electrically connected to a plurality of to-be-detected elements located in different detection regions.

2. The detection apparatus according to claim 1, wherein the same second signal line is configured to be electrically connected to a plurality of to-be-detected elements located in different detection regions.

3. The detection apparatus according to claim 1, further comprising a first conductive portion located in the detection region and connected to the first signal line, wherein the first signal line is connected to the to-be-detected element through the first conductive portion; and/or
the detection apparatus further comprises a second conductive portion located in the detection region and connected to the second signal line; and the second signal line is connected to the to-be-detected element through the second conductive portion.

4. The detection apparatus according to claim 1, further comprising a driving circuit disposed in the detection region, wherein the driving circuit is connected to the to-be-detected element; and the first signal line and the second signal line are connected to the driving circuit to control turn-on or turn-off of the driving circuit, whereby an operating state of the to-be-detected element is controlled.

5. The detection apparatus according to claim 1, wherein each of the at least one detection region comprises a space for accommodating a plurality of to-be-detected elements;
the plurality of first signal lines comprise at least one of first signal lines connected in one-to-one correspondence to at least one of the to-be-detected elements located in the same detection region and/or a first signal line connected to at least one of the to-be-detected elements located in the same detection region; and
the plurality of second signal lines comprise at least one of second signal lines connected in one-to-one correspondence to at least one of the to-be-detected elements located in the same detection region and/or a second signal line connected to at least one of the to-be-detected elements located in the same detection region.

6. The detection apparatus according to claim 5, wherein an arrangement direction of the plurality of to-be-detected elements located in the same detection region is the same as an arrangement direction of the correspondingly connected first signal lines.

7. The detection apparatus according to claim 6, wherein an arrangement order of the plurality of to-be-detected elements located in the same detection region is the same as an arrangement order of the correspondingly connected first signal lines.

8. The detection apparatus according to claim 1, wherein the substrate comprises a plurality of island structures spaced apart from each other, and connection portions configured to connect adjacent island structures; and the island structures each are configured to provide a space for accommodating a plurality of to-be-detected elements.

9. The detection apparatus according to claim 8, wherein the connection portions each are provided with a weakened portion; and a structural strength of the weakened portion is less than a structural strength at another position on the connection portion, whereby the weakened portion serves as a disconnection position for disconnecting connected island structures.

10. The detection apparatus according to claim 8, wherein the connection portions each comprise a base and a metal wiring layer stacked on a side of the base; and/or
the connection portions each comprise highly doped polycrystalline silicon;
the plurality of first signal lines are respectively disposed on the connection portions; and/or
the plurality of second signal lines are respectively disposed on the connection portions.

11. The detection apparatus according to claim 8, wherein the island structures are made of a material comprising silicon; and/or
a thickness of each of the island structures is W, wherein W satisfies 20 μm≤W≤500 μm.

12. A detection method for light-emitting elements, configured to detect the light-emitting elements through the detection apparatus according to claim 1, and comprising following steps:
transmitting, according to a preset signal transmission rule, the first-type signal to the to-be-detected light-emitting elements through the first signal lines, and the second-type signal to the to-be-detected light-emitting elements through the second signal lines, wherein the to-be-detected light-emitting elements are respectively disposed in a plurality of detection regions of the substrate; the to-be-detected light-emitting elements each are connected to the first signal lines and the second signal lines; and the same first signal line is configured to be electrically connected to a plurality of to-be-detected light-emitting elements located in different detection regions; and
performing light emission identification on the to-be-detected light-emitting elements in each of the detection regions, identifying a to-be-detected light-emitting element with abnormal light emission, and determining the to-be-detected light-emitting element with abnormal light emission as a faulty element.
